(19) United States
(12) Patent Application Publication
(10) Pub. No.: US 2022/0122815 A1
(43) Pub. Date: Apr. 21, 2022

(54) SYSTEMS AND METHODS FOR UNPRECEDENTED CRYSTALLINE QUALITY IN PHYSICAL VAPOR DEPOSITION-BASED ULTRA-THIN ALUMINUM NITRIDE FILMS

(71) Applicant: OEM Group, LLC, Gilbert, AZ (US)

(72) Inventors: Marc-Andre Lariviere, Mesa, AZ (US); Juan M. Rios Reyes, Exeter, CA (US); Nitin Choudhary, Mesa, AZ (US); Chao Li, Chandler, AZ (US); Brendan V. Trang, La Puente, CA (US)

(73) Assignee: OEM Group, LLC, Gilbert, AZ (US)

(21) Appl. No.: 17/488,169

(22) Filed: Sep. 28, 2021

Related U.S. Application Data
(60) Provisional application No. 63/092,207, filed on Oct. 15, 2020.

(51) Int. Cl. H01J 37/32; H01J 37/34; H01L 21/02; H01L 21/3065; C23C 14/35; C23C 14/50; C23C 14/06

(52) U.S. Cl. CPC H01J 37/32715; H01J 37/3405; H01L 21/0254; H01L 21/02631; H01L 21/3065; H01J 2237/332; C23C 14/505; C23C 14/0617; H01J 2237/20214; H01J 2237/334; C23C 14/35

(57) ABSTRACT

The present invention provides a method for depositing an ultra-thin film onto a wafer. The method comprising the following steps. A sputtering chamber is provided wherein the sputtering chamber is collectively defined by a wafer handling apparatus and a magnetron. The wafer is placed onto a wafer chuck of the wafer handling apparatus. The wafer chuck is moved to a first distance to the magnetron. A gas is introduced into the sputtering chamber such that the gas is separated into a plasma, wherein the plasma includes gas ions. A first negative potential is applied to at least one sputtering target of the magnetron while the wafer chuck with the wafer is at the first distance to the magnetron. The wafer chuck is moved to a second distance to the magnetron. A second negative potential is applied to at least one sputtering target of the magnetron while the wafer chuck with the wafer is at the second distance to the magnetron. The wafer is removed from the wafer chuck after the application of the second negative potential to at least one sputtering target of the magnetron.

### CROSS REFERENCES TO RELATED APPLICATIONS

This application claims priority from and is related to commonly owned U.S. Provisional Patent Application Ser. No. 63/092,207 filed Oct. 15, 2020, entitled: SYSTEMS AND METHODS FOR UNPRECEDENTED CRYSTALLINE QUALITY IN PHYSICAL VAPOR DEPOSITION-BASED ULTRA-THIN ALUMINUM NITRIDE FILMS, this Provisional Patent Application incorporated by reference herein.

### FIELD OF THE INVENTION

The present disclosure generally relates to semiconductor manufacturing; and in particular, to systems and methods for improved crystalline quality in physical vapor deposition-based aluminum nitride films.

### BACKGROUND OF THE INVENTION

Gallium-nitride (GaN) has been widely used in LEDs and high-power microelectronic devices owing to its wide band gap. GaN thin film integration on silicon (Si) wafers offers tremendous potential in large-scale CMOS devices. However, there is a significant challenge to grow epitaxial GaN films directly on Si wafers because of large lattice mismatch and difference in thermal expansion coefficients. This issue can be overcome by the use of compatible buffer layers sandwiched between Si and GaN to minimize the lattice mismatch and allow the growth of epitaxial GaN films. Among various buffer layers such as silicon carbide (SiC), aluminum nitride (AlN), gallium arsenide (GaAs), and silicon nitride (Si₃N₄), AlN has been known to promote the highest quality, crack-free growth of GaN films. As the quality of AlN buffer layers is crucial, several deposition techniques have been employed including molecular beam epitaxy (MBE), atomic layer deposition, and metal organic chemical vapor deposition (MOCVD), which are either toxic in nature or require expensive setup. Physical Vapor Deposition (PVD) is a better alternative to the aforementioned techniques for its high growth rate. It's also necessary to ensure the consistency and quality of PVD-based AlN buffer layers.

Nothing in the prior art provides the benefits attendant with the present invention.

Therefore, it is an object of the present invention to provide an improvement which overcomes the inadequacies of the prior art devices and which is a significant contribution to the advancement of using a magnetron system.

Another object of the present invention is to provide a method for depositing an ultra-thin film onto a wafer, comprising providing a sputtering chamber, the sputtering chamber being collectively defined by a wafer handling apparatus and a magnetron; placing the wafer onto a wafer chuck of the wafer handling apparatus; moving the wafer chuck with the wafer to a first distance to the magnetron; introducing a gas into the sputtering chamber such that the gas is separated into a plasma, wherein the plasma includes gas ions; applying a first negative potential to at least one sputtering target of the magnetron while the wafer chuck with the wafer is at the first distance to the magnetron; rotating the wafer at a first rotational speed using the wafer chuck of the wafer handling apparatus during the application of the first negative potential to at least one sputtering target of the magnetron; and removing the wafer from the wafer chuck after the application of the first negative potential to at least one sputtering target of the magnetron.

Yet another object of the present invention is to provide a method for depositing an ultra-thin film onto a wafer, comprising providing a sputtering chamber, the sputtering chamber being collectively defined by a wafer handling apparatus and a magnetron; placing the wafer onto a wafer chuck of the wafer handling apparatus; moving the wafer chuck with the wafer to a first distance to the magnetron; introducing a gas into the sputtering chamber such that the gas is separated into a plasma, wherein the plasma includes gas ions; and applying a first negative potential to at least one sputtering target of the magnetron while the wafer chuck with the wafer is at the first distance to the magnetron; moving the wafer chuck with the wafer to a second distance to the magnetron; applying a second negative potential to at least one sputtering target of the magnetron while the wafer chuck with the wafer is at the second distance to the magnetron; and removing the wafer from the wafer chuck after the application of the second negative potential to at least one sputtering target of the magnetron.

Still yet another object of the present invention is to provide a system for depositing an ultra-thin film onto a wafer, comprising a sputtering chamber; a magnet assembly positioned proximate to a sputtering target and configured for manipulating a magnetic field at a surface of the sputtering target; a wafer handling apparatus positioned above the sputtering target having a vertical rod and a wafer chuck, the wafer chuck having a thermoelectric assembly configured to apply heat to the wafer; a lifting assembly for lifting or lowering the wafer chuck; a rotational assembly in communication with the vertical rod for rotating the wafer chuck; and a plurality of pin assemblies to receive the wafer and hold the wafer against an underside of the wafer chuck.

The foregoing has outlined some of the pertinent objects of the present invention. These objects should be construed to be merely illustrative of some of the more prominent features and applications of the intended invention. Many other beneficial results can be attained by applying the disclosed invention in a different manner or modifying the invention within the scope of the disclosure. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

The invention described herein provides systems and methods for unprecedented crystalline quality in physical vapor deposition-based ultra-thin aluminum nitride films.

A feature of the present invention is to provide a method for depositing an ultra-thin film onto a wafer. The method comprising the following steps. A sputtering chamber is provided wherein the sputtering chamber is collectively defined by a wafer handling apparatus and a magnetron. The wafer is placed onto a wafer chuck of the wafer handling apparatus. The wafer can be secured against an underside of the wafer chuck of the wafer handling apparatus using a plurality of pin assemblies. The wafer chuck is moved to a first distance to the magnetron. A gas is introduced into the sputtering chamber such that the gas is separated into a plasma, wherein the plasma includes gas ions. A first negative potential is applied to at least one sputtering target of the magnetron while the wafer chuck with the wafer is at the first distance to the magnetron. The wafer is rotated at a first rotational speed using the wafer chuck of the wafer handling apparatus during the application of the first negative potential to at least one sputtering target of the magnetron. The wafer is removed from the wafer chuck after the application of the first negative potential to at least one sputtering target of the magnetron. The wafer can be continuously rotated at the first rotational speed using the wafer chuck of the wafer handling apparatus during the application of the first negative potential to at least one sputtering target of the magnetron. The wafer can be variably rotated at different rotational speeds using the wafer chuck of the wafer handling apparatus during the application of the first negative potential to at least one sputtering target of the magnetron. An in-situ etching process can be applied to the wafer prior to applying the first negative potential to the sputtering target of the magnetron. The method can further comprise moving the wafer chuck with the wafer to a second distance to the magnetron; applying a second negative potential to at least one sputtering target of the magnetron while the wafer chuck with the wafer is at the second distance to the magnetron; and removing the wafer from the wafer chuck after the application of the second negative potential to at least one sputtering target of the magnetron. The method can further comprise rotating the wafer at a second rotational speed using the wafer chuck of the wafer handling apparatus during the application of the second negative potential to at least one sputtering target of the magnetron. The method can further comprise continuously rotating the wafer at the second rotational speed using the wafer chuck of the wafer handling apparatus during the application of the second negative potential to at least one sputtering target of the magnetron. The method can further comprise variably rotating the wafer at different rotational speeds using the wafer chuck of the wafer handling apparatus during the application of the second negative potential to at least one sputtering target of the magnetron. The wafer can be heated through the wafer chuck of the wafer handling apparatus. The wafer can be heated to a temperature within a range of 400-650 degrees Celsius. The wafer chuck can be lowered into the sputtering chamber by a vertical rod, and wherein the vertical rod is in operative association with a lifting assembly of the wafer handling apparatus. The wafer chuck can be rotated by a vertical rod, and wherein the vertical rod is in operative association with a rotational assembly of the wafer handling apparatus. The wafer chuck can be rotated between 10-50 revolutions per minute. At least one pin of the plurality of pin assemblies can further comprise a vertical section and a lateral section. At least one pin of the plurality of pin assemblies can further comprise a cap. Each pin of the plurality of pin assemblies can be disposed through a respective securing piece. Each vertical section of each pin can be sheathed by a spring located between the pin cap and the securing piece.

Another feature of the present invention is to provide a method for depositing an ultra-thin film onto a wafer. The method comprising the following steps. A sputtering chamber is provided wherein the sputtering chamber is collectively defined by a wafer handling apparatus and a magnetron. The wafer is placed onto a wafer chuck of the wafer handling apparatus. The wafer can be secured against an underside of the wafer chuck of the wafer handling apparatus using a plurality of pin assemblies. The wafer chuck is moved to a first distance to the magnetron. A gas is introduced into the sputtering chamber such that the gas is separated into a plasma, wherein the plasma includes gas ions. A first negative potential is applied to at least one sputtering target of the magnetron while the wafer chuck with the wafer is at the first distance to the magnetron. The wafer chuck is moved to a second distance to the magnetron. A second negative potential is applied to at least one sputtering target of the magnetron while the wafer chuck with the wafer is at the second distance to the magnetron. The wafer is removed from the wafer chuck after the application of the second negative potential to at least one sputtering target of the magnetron. An in-situ etching process can be applied to the wafer prior to applying the first negative potential to the sputtering target of the magnetron. The method can further comprise rotating the wafer at a first rotational speed using the wafer chuck of the wafer handling apparatus during the application of the first negative potential to at least one sputtering target of the magnetron. The wafer can be continuously rotated at the first rotational speed using the wafer chuck of the wafer handling apparatus during the application of the first negative potential to at least one sputtering target of the magnetron. The wafer can be variably rotated at different rotational speeds using the wafer chuck of the wafer handling apparatus during the application of the first negative potential to at least one sputtering target of the magnetron. The method can further comprise rotating the wafer at a second rotational speed using the wafer chuck of the wafer handling apparatus during the application of the second negative potential to at least one sputtering target of the magnetron. The wafer can be continuously rotated at the second rotational speed using the wafer chuck of the wafer handling apparatus during the application of the second negative potential to at least one sputtering target of the magnetron. The wafer can be variably rotated at different rotational speeds using the wafer chuck of the wafer handling apparatus during the application of the second negative potential to at least one sputtering target of the magnetron. The wafer can be heated through the wafer chuck of the wafer handling apparatus. The wafer can be heated to a temperature within a range of 400-650 degrees Celsius. The wafer chuck can be lowered into the sputtering chamber by a vertical rod, and wherein the vertical rod is in operative association with a lifting assembly of the wafer handling apparatus. The wafer chuck can be rotated by a vertical rod, and wherein the vertical rod is in operative association with a rotational assembly of the wafer handling apparatus. The wafer chuck can be rotated between 10-50 revolutions per minute. At least one pin of the plurality of pin assemblies can further comprise a vertical section and a lateral section. At least one pin of the plurality of pin assemblies can further comprise a cap. Each pin of the plurality of pin assemblies can be disposed through a respective securing piece. Each vertical section of each pin can be sheathed by a spring located between the pin cap and the securing piece.

Yet another feature of the present invention is to provide a system for depositing an ultra-thin film onto a wafer. The system comprises a sputtering chamber and a magnet assembly positioned proximate to a sputtering target and configured for manipulating a magnetic field at a surface of the sputtering target. A wafer handling apparatus positioned above the sputtering target that has a vertical rod and a wafer chuck. The wafer chuck has a thermoelectric assembly configured to apply heat to the wafer. A lifting assembly for lifting or lowering the wafer chuck. A rotational assembly in communication with the vertical rod for rotating the wafer chuck. A plurality of pin assemblies to receive the wafer and hold the wafer against an underside of the wafer chuck. The magnet assembly can further comprise an outer magnet assembly that has a first plurality of magnet pairs, an inner magnet assembly that has a second plurality of magnet pairs, and a plurality of pole pieces, wherein each magnet assembly contacts at least two pole pieces of the plurality of pole pieces. The wafer handling assembly can further comprise a main plate positioned above the magnet assembly such that the wafer chuck and vertical rod are lowered below the main plate and above the sputtering target. The plurality of pin assemblies can be defined annularly around the wafer chuck for receipt of a wafer. At least one pin of the plurality of pin assemblies can further comprise a vertical section and a lateral section. At least one pin of the plurality of pin assemblies can further comprise a cap. Each pin of the plurality of pin assemblies can be disposed through a respective securing piece. Each vertical section of each pin can be sheathed by a spring located between the pin cap and the securing piece.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

FIG. 1 is a perspective view showing a system for physical vapor deposition onto an arbitrary wafer including a wafer handling apparatus and a magnetron collectively defining a sputtering chamber;

FIG. 2 is an exploded front view of the system of FIG. 1 showing the wafer handling apparatus defining a wafer chuck engaged with a vertical rod that lowers the wafer chuck above the magnetron;

FIG. 3 is a cross-sectional view of the system of FIG. 1 showing the wafer handling apparatus and the magnetron that collectively define the sputtering chamber;

FIG. 4 is a perspective view showing the magnetron of the system of FIG. 1;

FIG. 5 is a front view showing an internal assembly of the magnetron of FIG. 4;

FIG. 6 is an exploded view showing the internal assembly of FIG. 5;

FIGS. 7A and 7B are perspective views showing respective outer and inner magnet assemblies of the internal assembly of FIG. 5;

FIG. 8 is a perspective view showing the wafer handling apparatus of the system of FIG. 1;

FIG. 9 is a front view showing the wafer handling apparatus of FIG. 8;

FIG. 10 is a bottom perspective view showing the wafer handling apparatus of FIG. 8;

FIG. 11 is a front view showing a wafer chuck of the wafer handling apparatus of FIG. 8;

FIG. 12 is a top perspective view showing the wafer chuck of FIG. 11;

FIG. 13 is a below perspective view showing the heated wafer chuck of FIG. 11;

FIGS. 14A and 14B are respective views of the pin assemblies of the water handling apparatus of FIG. 8 in a “wafer loading” position (FIG. 14A) and a “wafer processing” position (FIG. 14B) with the wafer present;

FIG. 15 is a front view showing a gas assembly associated with an upper frame and a lower frame of the wafer handling apparatus of FIG. 8;

FIG. 16 is a front view showing a thermoelectric assembly and shields of a wafer handling apparatus of FIG. 8; and

FIGS. 17A and 17B are respective partially exploded and assembled side views of the wafer chuck of the wafer handling apparatus of FIG. 8 and a baseplate of the magnetron of FIG. 4.

### DETAILED DESCRIPTION OF THE INVENTION

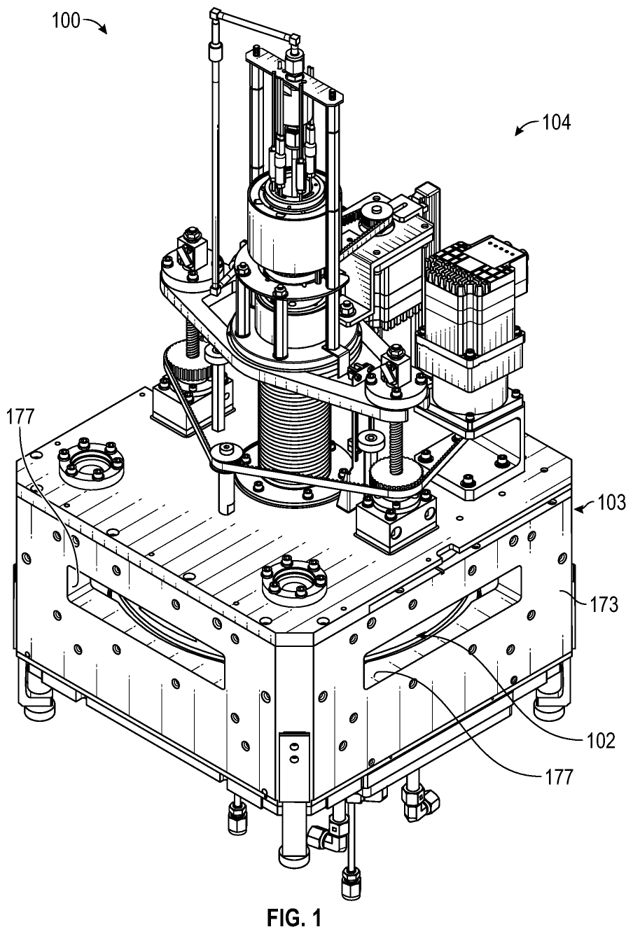

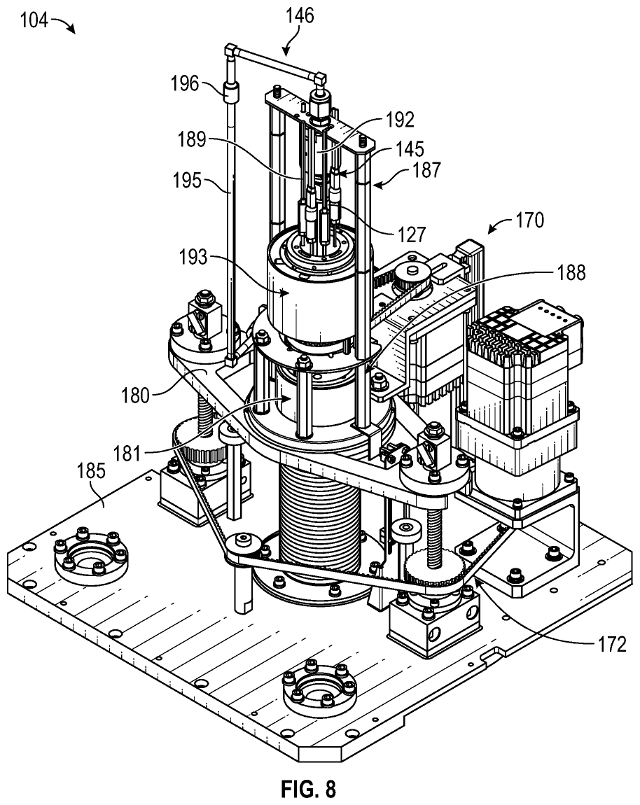

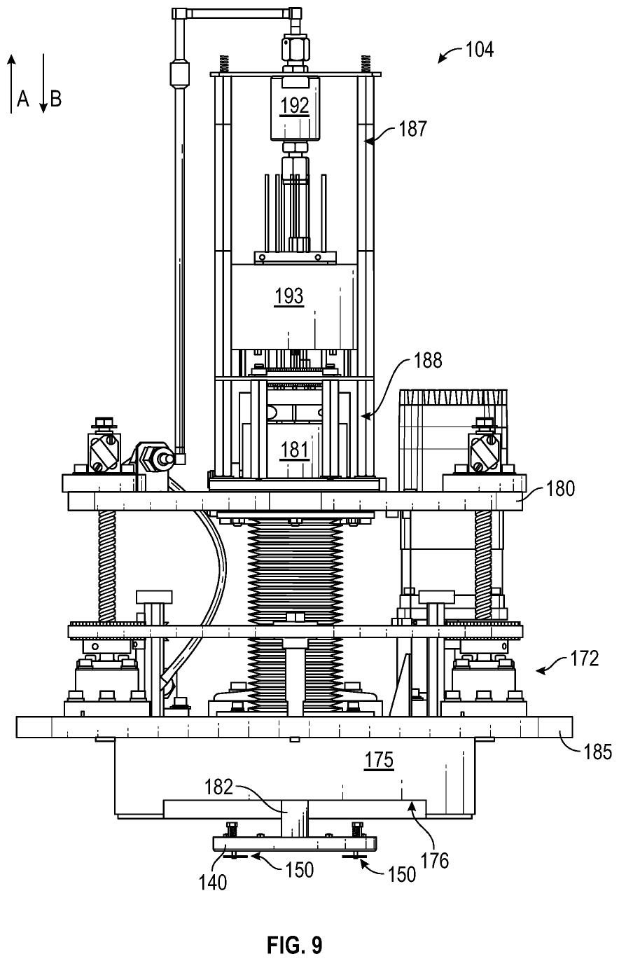

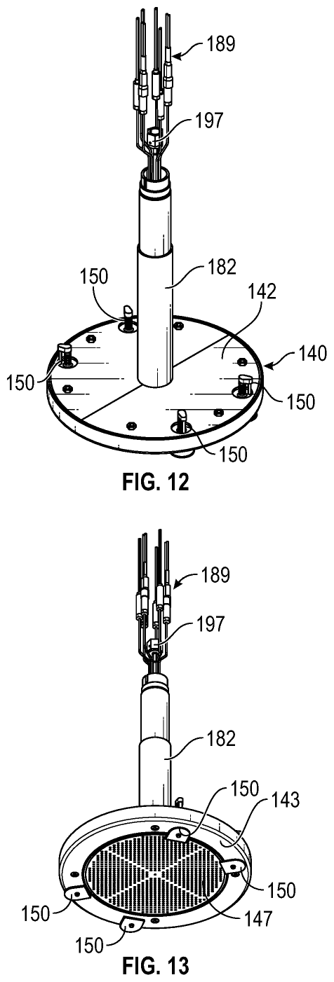

Various embodiments of a system and associated method for depositing an ultra-thin aluminum nitride (AlN) film onto an arbitrary wafer are disclosed herein. In particular, the system includes a magnetron and a lift-and-rotate wafer handling apparatus having a hot wafer chuck collectively defining a sputtering chamber operable for receiving a wafer, lowering the wafer into the sputtering chamber, and then depositing an AlN film onto the wafer. A film deposition method is disclosed in which the wafer is processed under specific conditions within the sputtering chamber to deposit the AlN film onto the wafer. The sputtering chamber and film deposition method, when used together, produces a full width at half maximum (FWHM) of about 2.0 degrees in 30 nm AlN film. Referring to the drawings, embodiments of a system and associated method for depositing an ultra-thin aluminum nitride film onto an arbitrary wafer are illustrated and generally indicated as 100 and 200 in FIGS. 1-17.

### System Overview

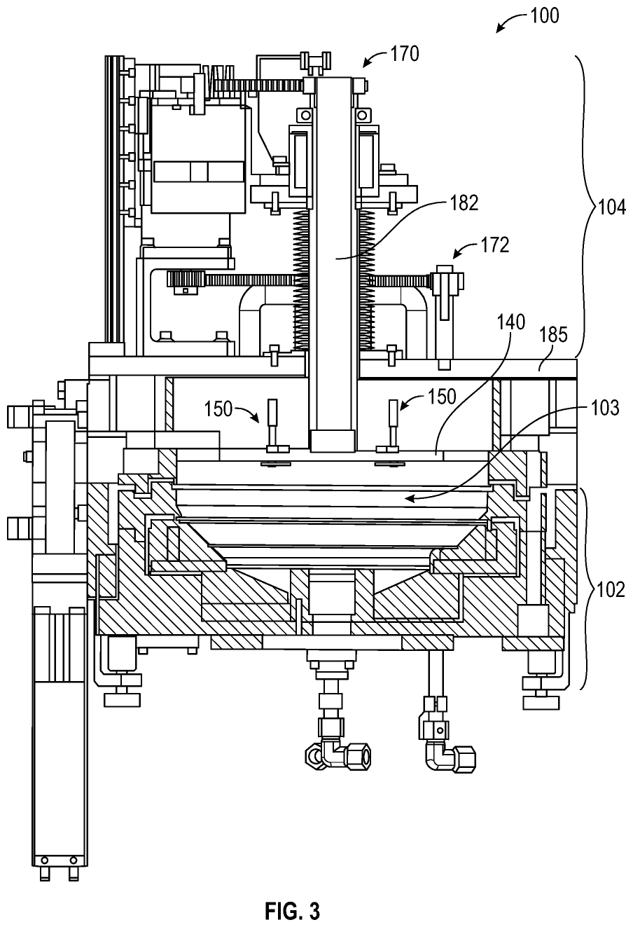

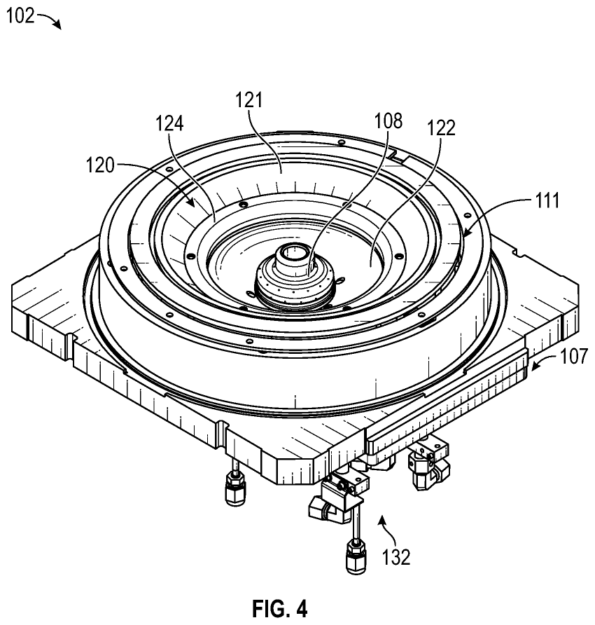

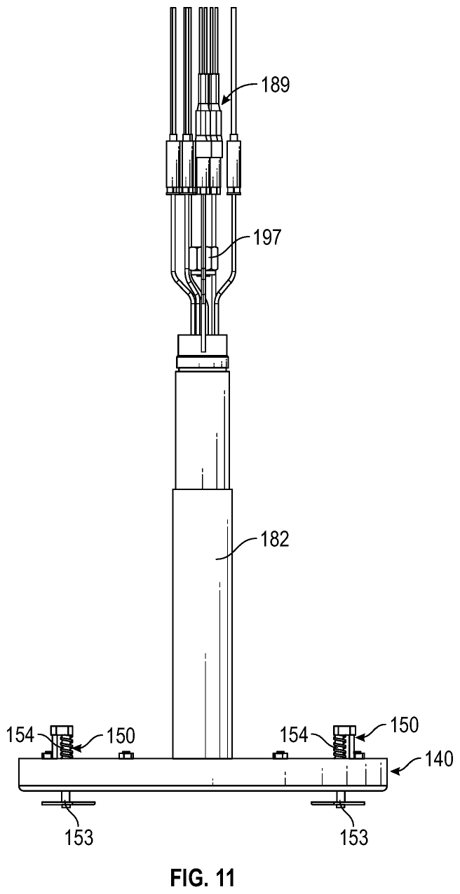

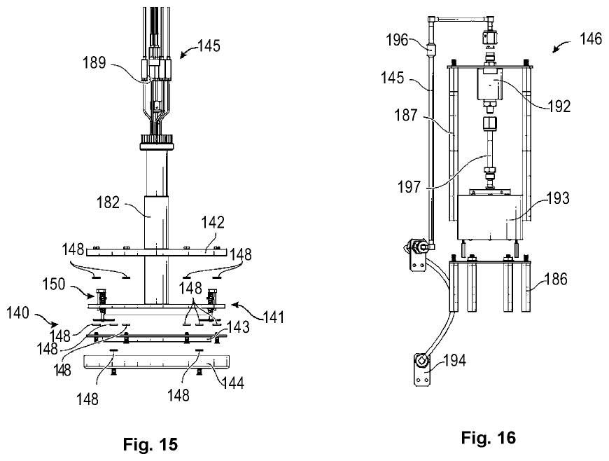

As shown in FIGS. 1-3, a system 100 for depositing an ultra-thin AlN film onto an arbitrary wafer 10 is shown including a magnetron 102 and a wafer handling apparatus 104 positioned above the magnetron 102. In some embodiments, a sputtering chamber 103 is defined as an enclosed space formed below the wafer handling apparatus 104 and above the magnetron 102, as shown in FIG. 3. In some embodiments, the sputtering chamber 103 is enclosed by a sputtering box 173 which may include one or more wafer slots 177 for insertion and removal of the wafer 10 to and from the sputtering chamber 103. In one method, the wafer 10 is lowered into the sputtering chamber 103 by the wafer handling apparatus 104 and held above the magnetron 102. The magnetron 102 of the system 100 includes a negatively biased target 120 (FIG. 4) that faces the wafer 10 for deposition of material from the target 120 onto the wafer 10. An inert gas is introduced into the system 100 under ultra-high vacuum such that gas is ionized into positively charged ions by free electrons and these ions are attracted towards the negatively biased target 120. When the gas ions strike the surface of the target 120, molecules of material are knocked off of the target 120 and adhere to the wafer 10. In some embodiments, the wafer handling apparatus 104 of the target system 100 is operable for engaging the wafer 10 and lifting, lowering, and/or rotating the wafer 10 over the target 120 of the magnetron 102 for deposition onto the wafer 10 at controlled height and rotational speed of the wafer 10 relative to the target 120. In some embodiments, the wafer handling apparatus 104 includes a wafer chuck 140 for engaging the wafer 10 and using a plurality of pin assemblies 150 (FIG. 11) to receive the wafer and hold the wafer against an underside of the wafer chuck 140. The wafer chuck 140 also aids in processing the wafer 10 while the wafer 10 is engaged by the wafer chuck 140. In some embodiments, the wafer chuck 140 is operable for applying heat to the wafer 10 during the sputtering process through a thermoelectric assembly 145 (FIG. 15). In some embodiments, the system 100 further includes a computing system 300 for control of the magnetron 102 and the wafer handling apparatus 104 and to provide real-time stress control on the wafer 10 and adjustment of the sputtering process.

### Method Overview

A method of depositing an ultra-thin film onto an arbitrary wafer 10 is disclosed herein. The wafer 10 is received by a plurality of pin assemblies 150 (FIG. 11) and secured against the wafer chuck 140 (FIG. 11) of the wafer handling apparatus 104 before being lowered into the sputtering chamber 103 to a first distance positioned above the magnetron 102. The wafer 10 is then pre-treated by application of an in-situ etching process and pre-heating of the wafer 10. The wafer 10 is heated to a temperature within a range of 400-650 degrees Celsius by the thermoelectric assembly 145 of the wafer chuck 140. In some embodiments, pre-heating of the wafer 10 by the wafer chuck 140 (FIG. 13) is performed immediately after the etching process. Once heated, the wafer 10 is rotated by the wafer handling apparatus 104 at a first rotational speed between 10-50revolutions per minute. An ultra-thin film is deposited onto the wafer 10 while the wafer 10 is heated to a temperature between 400 and 650 degrees Celsius and is being rotated by the wafer handling apparatus 104. The deposition includes introducing a reactive gas flow into the sputtering chamber 103 and applying a first negative potential to at least one sputtering target of the magnetron 102 to activate the sputtering process. The wafer 10 is allowed to cool following film deposition. The wafer 10 is released from the wafer chuck 140 of the wafer handling apparatus 102 and can be taken out of the sputtering chamber 103 through a loadlock slot 176.

In another embodiment of the present invention, another method of depositing an ultra-thin film onto an arbitrary wafer 10 is disclosed herein. The wafer 10 is received by a plurality of pin assemblies 150 (FIG. 11) and secured against the wafer chuck 140 (FIG. 11) of the wafer handling apparatus 104 before being lowered into the sputtering chamber 103 to a first distance positioned above the magnetron 102. The wafer 10 is then pre-treated by application of an in-situ etching process and pre-heating of the wafer 10. The wafer 10 is heated to a temperature within a range of 400-650 degrees Celsius by the thermoelectric assembly 145 of the wafer chuck 140. In some embodiments, pre-heating of the wafer 10 by the wafer chuck 140 (FIG. 13) is performed immediately after the etching process. Once heated, the wafer 10 is rotated by the wafer handling apparatus 104 at a first rotational speed between 10-50 revolutions per minute. An AlN film is deposited onto the wafer 10 while the wafer 10 is heated to a temperature between 400 and 650 degrees Celsius and is being rotated by the wafer handling apparatus 104. The deposition includes introducing a reactive gas flow into the sputtering chamber 103 and applying a first negative potential to at least one sputtering target of the magnetron 102 to activate the sputtering process. Then, the wafer 10 is rotated by the wafer handling apparatus 104 at a second rotational speed between 10-50 revolutions per minute. An ultra-thin film is deposited onto the wafer 10 while the wafer 10 is heated to a temperature between 400 and 650 degrees Celsius and is being rotated by the wafer handling apparatus 104. The deposition includes introducing a reactive gas flow into the sputtering chamber 103 and applying a second negative potential to at least one sputtering target of the magnetron 102 to activate the sputtering process. The wafer 10 is allowed to cool following film deposition. The wafer 10 is released from the wafer chuck 140 of the wafer handling apparatus 102 and can be taken out of the sputtering chamber 103 through a loadlock slot 176.

In any embodiment of the present invention, the first rotational speed of the wafer by the wafer chuck can be equal, greater or less than the second rotational speed of the wafer by the wafer chuck.

In any embodiment of the present invention, the rotational speed of the wafer by the wafer chuck can be adjusted discreetly, continuously and/or variably. The adjustment to the rotational speed of the wafer by the wafer chuck can be before, during and/or after the application of a negative potential to at least one sputtering target of the magnetron.

In any embodiment of the present invention, the first distance to the magnetron can be equal, greater or less than the second distance to the magnetron.

In any embodiment of the present invention, the distance to the magnetron can adjusted discreetly, continuously and/or variably. The adjustment to the distance to the magnetron can be before, during and/or after the application of a negative potential to at least one sputtering target of the magnetron.

In any embodiment of the present invention, the first negative potential to at least one sputtering target of the magnetron can be equal, greater or less than the second negative potential to at least one sputtering target of the magnetron.

In any embodiment of the present invention, the application of a negative potential to at least one sputtering target of the magnetron can adjusted discreetly, continuously and/or variably.

In any embodiment of the present invention, the application of the first negative potential to at least one sputtering target and the application of the second negative potential to at least one sputtering target can be to the same sputtering target or to different sputtering targets.

Previous technologies deposit AlN layers for GaN epitaxy employing expensive tools using toxic precursors or higher growth temperatures (>1000° C.) such as molecular beam epitaxy and metal organic chemical vapor deposition. In contrast, the system 100 and associated method 200 enable high quality growth of ultra-thin AlN layers at relatively low cost, with high compatibility for CMOS integration, low thermal budget, and in-situ residual stress control.

Magnetron

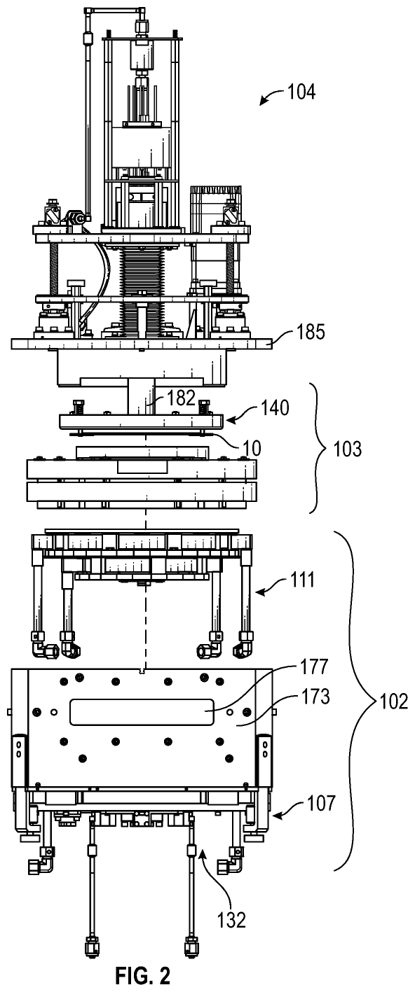

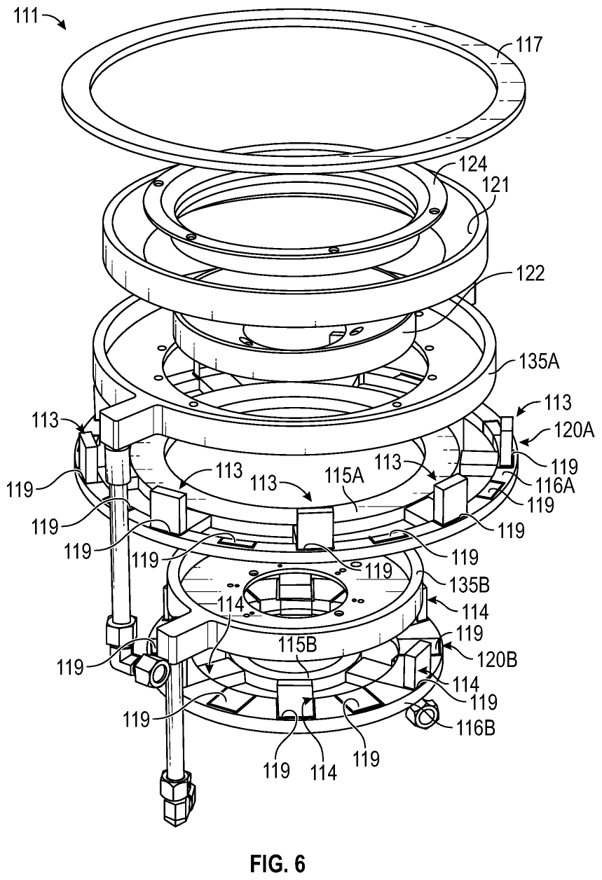

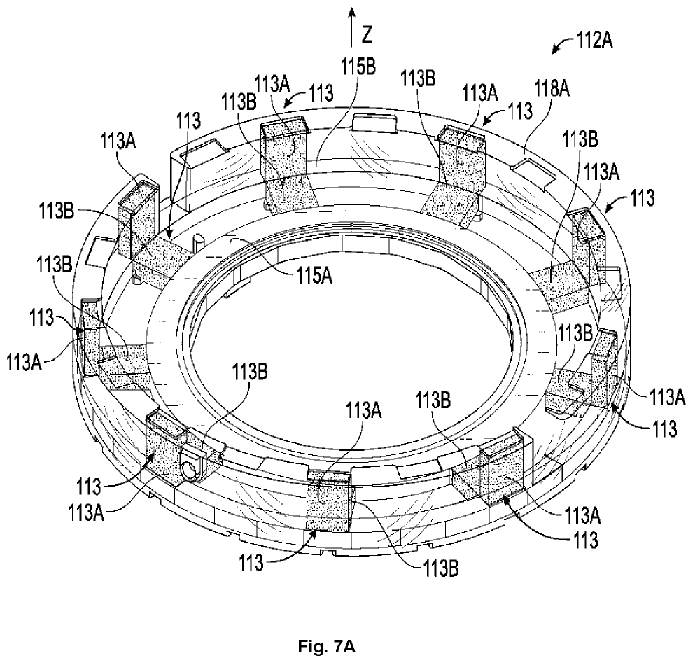

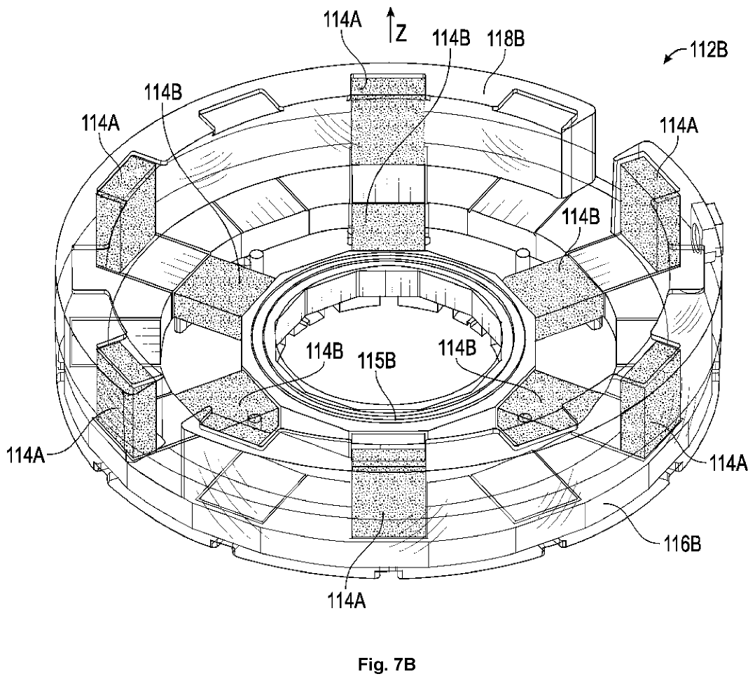

Referring to FIGS. 2-7, the magnetron 102 is shown defining a baseplate assembly 107 and a negatively charged target 120 (FIG. 4) with the target 120 resting within the baseplate assembly 107. The magnetron 102 further includes an internal assembly 111 situated directly beneath the target 120, the internal assembly 111 having an outer magnetic assembly 112A and an inner magnetic assembly 112B (FIG. 6) as well as an outer water jacket assembly 135A and an inner water jacket assembly 135B (FIG. 6). The magnetic assemblies 112A and 112B enable precise control of the magnetic field at the target 120 such that electrons are confined to the surface of the negatively charged target 120. The electrons enhance the ionization near the target 120 and newly formed ions are attracted towards the target 120 such that molecules are ejected from the target 120 and adhere to the wafer in the form of thin film. Control of the magnetic field by the magnetic assemblies 112A and 112B enables confinement of the electrons to particular areas of the target 120, thus enabling control of the sputtering process. In some embodiments, the magnetic assemblies 112A and 112B are each encased in a resin casing 118A and 118B (FIGS. 7A and 7B). As shown, the baseplate assembly 107 further includes a gas tower 108 (FIG. 4) extending through respective centers of the internal assembly 111 and the target 120 as well as a power feedthrough (not shown) for providing power to the magnetic assemblies 112A and 112B while the sputtering chamber 103 is under ultra-high vacuum. The magnetron 102 also includes a cooling plate 137 for cooling the power feedthrough 137 and the baseplate assembly 107 positioned underneath the internal assembly 111. In addition, a magnetron gas distribution system 132 is in fluid flow communication with the gas tower 108 when the magnetron 102 is assembled for introducing an inert gas into the sputtering chamber 103.

Referring to FIG. 4, the target 120 includes an outer concentric target 121 and an inner concentric target 122, and in some embodiments the target 120 is negatively biased. When in use within the sputtering chamber 103, positively charged gas ions are attracted towards the negatively charged outer concentric target 121 and inner concentric target 122. Specifically, the positively charged gas ions are attracted to the target 120 This causes material from the outer concentric target 121 and the inner concentric target 122 to be ejected from their respective surfaces by momentum transfer from the positively charged gas ions and adhere to the wafer 10 within the sputtering chamber 103.

In some embodiments, to deposit an AlN film onto the wafer 10, the outer concentric target 121 and the inner concentric target 122 are comprised of aluminum. In some embodiments, the outer concentric target 121 and the inner concentric target 122 are separated by or otherwise electrically isolated from each other by an annular target shield 124. The annular target shield 124 is located between the outer concentric target 121 and the inner concentric target 122 to provide structural support and/or electrical isolation.

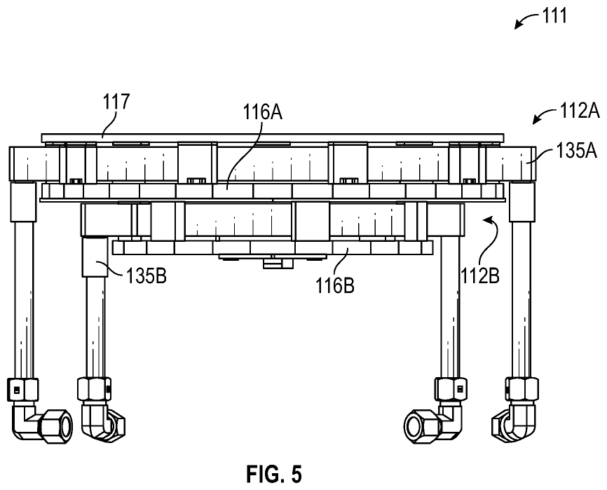

As discussed above and as shown in FIGS. 5 and 6, the internal assembly 111 further includes magnetic assemblies 112A and 112B configured to induce a magnetic field to confine negatively charged electrons to a surface of the outer and inner concentric targets 121 and 122, thus maintaining higher sputter rates by controlling the gas ionization near the target 120. The magnetic assemblies 112A and 112B mirror a concentric configuration of the target 120.

Referring to FIGS. 5-6B, the outer and inner magnet assemblies 112A and 112B are shown. As discussed above, the outer and inner magnet assemblies 112A and 112B induce a magnetic field within the sputtering chamber 103 (FIG. 3). The diameter of the inner magnet assembly 112B is less than that of the outer magnet assembly 112A, as shown in FIG. 6. In some embodiments, the diameter of the outer magnet assembly 112A is 11 inches and the diameter of the inner magnet assembly 112B is 7 inches; however, embodiments of the magnet assembly 112 are not limited to these diameters. The outer magnet assembly 112A, includes a plurality of magnet pairs 113 (FIG. 7A) arranged concentrically around a central axis Z. Similarly, the inner magnet assembly 112B, includes a plurality of magnet pairs 114 (FIG. 7B) arranged concentrically around a central axis Z.

Referring to FIGS. 7A and 7B, each magnet pair 113 of the outer magnet assembly 112A includes a respective vertically oriented magnet 113A aligned with the central axis Z and a respective horizontally oriented magnet 113B oriented perpendicular to the respective vertically oriented magnet 113A aligned with central axis Z. Similarly, each magnet pair 114 of the inner magnet assembly 112B includes a respective vertically oriented magnet 114A aligned with the central axis Z and a respective horizontally oriented magnet 114B oriented perpendicular to the respective vertically oriented magnet 114A aligned with central axis Z. Each magnet 113A, 113B, 114A and 114B is a permanent magnet.

In some embodiments shown in FIGS. 6-7B, the magnetic assemblies 112A and 112B define a magnetic circuit which is completed by connection between components of the outer magnet assembly 112A and the inner magnetic assembly 112B. In some embodiments, outer magnet assembly 112A includes a first outer pole piece 116A located underneath each vertically oriented magnet 113A and positioned externally relative to each horizontally oriented magnet 113B for structural support and for completion of a magnetic connection between each vertically oriented magnet 113A and each horizontally oriented magnet 113B. Further, the outer magnet assembly 112A includes a first inner pole piece 115A located internal to each horizontally oriented magnet 113B for additional structural support and for completion of a magnetic connection between each horizontally oriented magnet 113B of the outer magnet assembly 112A and each vertically oriented magnet 113A of the inner magnet assembly 112B. Similarly, the inner magnet assembly 112B includes a second outer pole piece 116B located underneath each vertically oriented magnet 114A and positioned externally relative to each horizontally oriented magnet 114B for completion of a magnetic connection between each vertically oriented magnet 114A and each horizontally oriented magnet 114B, as well as a second inner pole piece 115B located internal to each horizontally oriented magnet 114B for structural support and completion of the magnetic connection. In some embodiments, an upper pole piece 117 is included above the outer magnet assembly 112A for completion of the magnetic circuit. In some embodiments, each pole piece including the upper pole piece 117, first and second outer pole pieces 116A and 116B, and first and second inner pole pieces 115A and 115B includes a plurality of self-alignment indentations 119 for receipt and alignment of each magnet 113A, 113B, 114A and 114B. Each pole piece 117, 115A, 115B, 116A and 116B forces each magnet 113A, 113B, 114A and 114B to magnetically align with the pole pieces 117, 115A, 115B, 116A and 116B, improving magnetic uniformity and magnetic flux through the permanent magnets 113A, 113B, 114A and 114B.

For formation of the outer magnet assembly 112A, each magnet pair 113 of the outer magnet assembly 112A is encased in a nonconductive resin 118A (not shown), to provide for structural support as well as to prevent the magnet pairs 113 from shifting. Similarly, for formation of the inner magnet assembly 112B, each magnet pair 114 of the inner magnet assembly 112B is encased in nonconductive resin 118B to provide structural support as well as to prevent the magnet pairs 114 from shifting. Further, in some embodiments, each pole piece 117, 115A, 115B, 116A and 116B are encapsulated within the nonconductive resin 118A and 118B.

### Wafer Handling Apparatus

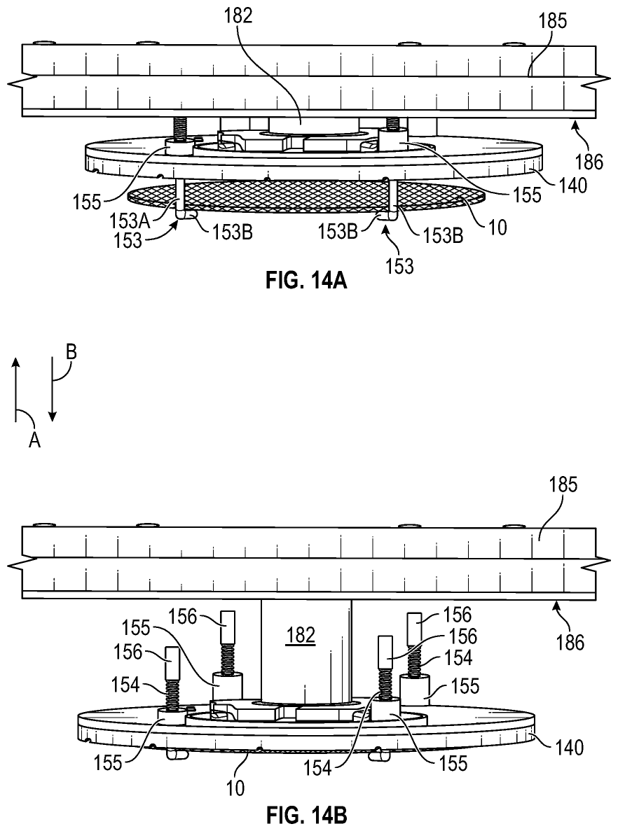

Referring to FIGS. 2 and 8-16, the wafer handling apparatus 104 is shown including the wafer chuck 140, the wafer chuck 140 being defined at a lower end of a vertical rod 182 and operable to receive the wafer 10. As shown, the vertical rod 182 is in association with a feedthrough plate 180 by a feedthrough 181, a lifting assembly 172 for lifting or lowering the feedthrough plate 180 and consequently the wafer chuck 140 in an axial direction A or B relative to the main plate 185, and a rotational assembly 170 in communication with the feedthrough 181 and vertical rod 182 for rotation of the vertical rod 182 and wafer chuck 140. As shown specifically in FIG. 14A, the lifting assembly 172 is operable for lifting the wafer chuck 140 into a “wafer loading” position such that the plurality of pin assemblies 150 disposed around the wafer chuck 140 open and receive a wafer 10. As shown in FIG. 14B, the lifting assembly 172 is also operable for lowering the wafer chuck 140 into the “wafer processing” position such that the plurality of pin assemblies 150 secure the wafer 10 against an underside of the wafer chuck 140.

The wafer handling apparatus 104 further includes the thermoelectric assembly 145 and a wafer chuck gas assembly 146 in association with the feedthrough 181, vertical rod 182 and wafer chuck 140 for introducing power and gas to the wafer chuck 140. The wafer handling apparatus 104 is configured to be positioned above the target 120 of the magnetron 102 (FIG. 4) for physical vapor deposition of material onto the wafer 10. As shown, a shield 175 is included between the target 120 of the magnetron 102 and the main plate 185 of the wafer handling apparatus 104 enclosing the sputtering chamber 103.

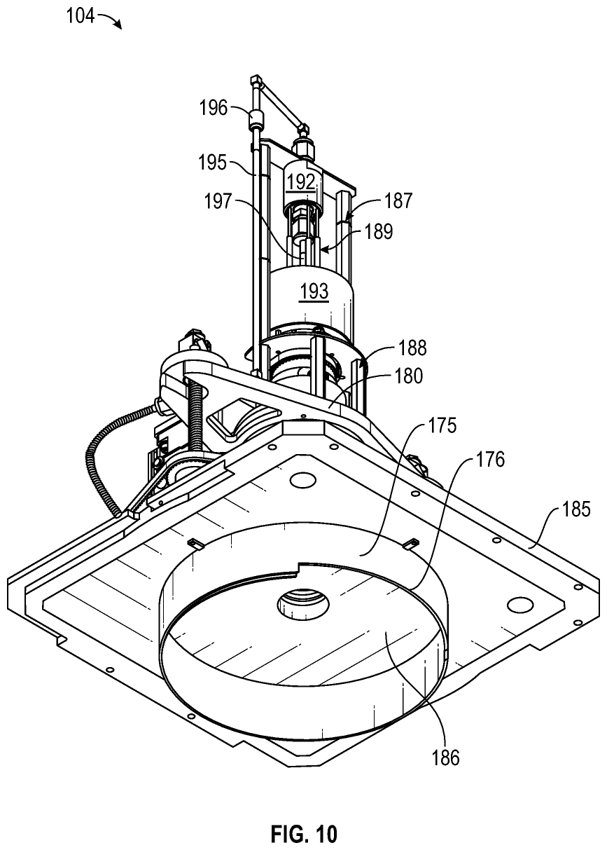

Referring to FIGS. 2, 14A and 14B, in some embodiments, the plurality of pin assemblies 150 include an “L”-shaped pin 153 including a vertical section 153A and a lateral section 153B. As shown specifically in FIG. 14A, each vertical section 153A includes a pin cap 156 which, while in the “wafer loading” position, contacts an underside 186 (FIG. 10) of the main plate 185. Each pin assembly 150 is disposed through a respective securing piece 155, each securing piece 155 being engaged to a circumferential edge of the wafer chuck 140. In some embodiments, each vertical section 153A of the pin 153 is sheathed by a spring 154 located between the pin cap 156 and the securing piece 155, allowing each pin assembly 150 to clutch the wafer 10 against the underside of the wafer chuck 140 while in the “wafer processing” position, as shown in FIG. 14B. Referring to FIG. 14A, when the vertical rod 182 and the wafer chuck 140 are lifted to the “wafer loading” position, each pin cap 156 contacts the underside 186 of the main plate 185 and compresses each spring 154 such that each respective pin 153 is lowered into the “wafer loading” position which maximizes a transfer gap between the lateral section 156 of each pin 153 and the underside of the wafer chuck 140 such that the wafer 10 may be inserted or removed. As shown in FIG. 14B, the vertical rod 182 and wafer chuck 140 are lowered out of the loading position, the pin cap 156 no longer contacts the underside 186 of the main plate 185 and each spring 154 will be allowed to assume a decompressed state and lift each pin 153 into the “wafer processing” position. In this “wafer processing” position, the wafer 10 is clamped in place to the underside of the wafer chuck 140 for processing by the lateral section 153B of each pin assembly 150.

FIGS. 11-13 illustrate the wafer chuck 140 defined at a lower end of the vertical rod 182. As shown, the wafer chuck 140 includes a plurality of pin assemblies 150 which are operable for receiving and securing the electronic wafer 10 against an underside of the wafer chuck 140. In some embodiments, the wafer chuck 140 is in electrical communication with the thermoelectric assembly 145 for applying heat to the wafer 10, and may include one or more heating elements (not shown) for generating heat. As shown in FIG. 15, the wafer chuck 140 includes an upper shield 142 defined above the wafer chuck component 141, a lower shield 143 defined below the wafer chuck component 141, and an outer covering 144 which encapsulates the wafer chuck component 141, all which serve the purpose of conserving heat and directing heat towards the wafer chuck component 141 and consequently, the electronic wafer 10. The wafer chuck 140 also includes a plurality of spacers 148 for electrical and thermal insulation. In some embodiments each of the plurality of spacers 148 is of a thermally and electrically insulating material such as ceramic.

Referring directly to FIG. 16, the wafer chuck gas assembly 146 comprises a gas inlet 194 in fluid flow communication with an external gas source (not shown) for introduction of a non-reactive gas, usually argon, for physical vapor deposition onto the wafer 10. The gas inlet 194 transfers gas from the external source (not shown) to a gas line 195. In some embodiments, a cryogenic break 196 is included along the gas line 195 to provide a safety measure if the gas line 195 is broken or otherwise damaged. As shown, the gas line 195 terminates at a rotary union 192 for maintaining fluid flow communication to the heated chuck 140 while the heated chuck 140 and vertical rod 182 are rotated by the rotational assembly 170. The rotary union 192 and gas line 195 are supported above the feedthrough plate 180 by the upper frame 187. A secondary gas line 197 connects the rotary union 192 to the wafer chuck 140 and in some embodiments extends downward through the vertical rod 182 to terminate in the one or more small apertures 147 (FIG. 13) defined on the underside of the wafer chuck 140. The introduction of gas at the wafer chuck 140 while heat is concurrently applied to the wafer 10 which allows for improved heat distribution uniformity across the wafer 10.

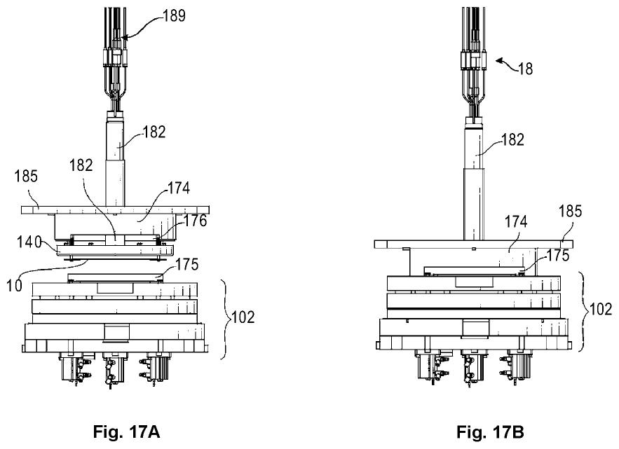

Referring to FIGS. 17A and 17B, the wafer chuck 10 is disposed above the target 120 of the magnetron 102 defining the sputtering chamber 103. The shield 175 is secured underneath the main plate 185 of the wafer handling apparatus 104 and encapsulates the wafer chuck 10 such that an environment within the sputtering chamber 103 is controlled in terms of gas flow rate and pressure, as specifically shown in the assembled view of FIG. 17B. As shown, the shield 175 includes the slot 176 for insertion of a wafer 10 when in the “wafer loading” position. While in the “wafer processing” position, when the wafer 10 is being processed within the sputtering chamber 103, the slot 176 is sealed by a slot guard 175 which is operable to move in and out of position to allow the wafer 10 to be inserted and removed when the wafer chuck 140 is in the “wafer loading” position and to seal the slot 176 when the wafer chuck 140 is in the “wafer processing” position.

### Physical Vapor Deposition Methodology

In one method of depositing ultra-thin AlN films onto an arbitrary wafer 10 using the sputtering chamber 103, the wafer 10 is first received and lowered into the sputtering chamber 103 by the wafer handling apparatus 102, pre-processed within the sputtering chamber 103, heated by the wafer chuck 140 of the wafer handling apparatus 104 and rotated by the wafer handling apparatus 104. Following these preliminary steps, the wafer 10 is subjected to a sputtering process in which power is applied to the magnetron 102. Following the sputtering process, the wafer is cooled and removed.

The wafer 10 is received by a plurality of pin assemblies 150 and clamped against a wafer chuck 140 of the wafer handling apparatus 104 and lowered into the sputtering chamber 103 and above the magnetron 102. In some embodiments, the wafer 10 is inserted into the sputtering chamber 103 through the slot 176 and received by the plurality of pin assemblies 150. Once received, the vertical rod 182 lifts the wafer chuck 140 to a maximum height relative to the main plate 185 into a “wafer loading” position by the lifting assembly 172. While in the “wafer loading” position, the plurality of pin assemblies 150 are operable to open and receive the wafer 10, as shown in FIG. 14A. The vertical rod 182 lowers the wafer chuck 10 to a variable “wafer processing” position relative to the main plate 185 within the sputtering chamber 103, as shown in 14B. In this position, the plurality of pin assemblies 150 physically clamp the wafer 10 against an underside of the wafer chuck 140.

The wafer 10 is pre-processed prior to deposition of the AlN film. The wafer 10 is subjected to an in-situ etching process, and the wafer 10 is pre-heated. In the in-situ etching process, the wafer 10 is etched at 300 W in argon gas plasma using an in-situ etch recipe. The wafer 10 is heated to a temperature between 400 and 650 degrees Celsius. Heating was performed after the etching process and the wafer 10 was heated gradually from room temperature to 400-650 degrees Celsius. Heat is applied to the wafer 10 via the thermoelectric assembly 145 of the wafer chuck 140. In some embodiments, as discussed above, a gas is introduced at the wafer chuck 140 by the wafer chuck gas assembly 146 while the wafer 10 is concurrently being heated to allow for uniformity of heat distribution across the wafer 10. The thermoelectric assembly 145 continues to maintain a temperature of the wafer 10 at a temperature within the range of 400-650 degrees Celsius through the sputtering process.

The wafer 10 is rotated within the sputtering chamber 103 by the rotational assembly 170 of the wafer handling apparatus 104. The vertical rod 182 rotates the wafer chuck 140 and the wafer 10 by operation of the rotational assembly 170 such that the wafer 10 may be contacted by molecules from the target 120 of the magnetron 102 while the wafer 10 is being rotated. In some embodiments, a rate of rotation is a rate within the range of 10-50 rotations per minute (rpm). The rotational assembly 170 continues to rotate the wafer 10 through the sputtering process, offering rotation of the wafer 10 with in-situ wafer heating at high temperatures. The magnetron 102 applies a sputtering process to the wafer 10. An inert gas is introduced into the sputtering chamber 103 via the gas tower 108 of the magnetron 102. In some embodiments, the gas is argon (Ar) and nitrogen (N₂) and are introduced at respective rates of 5-10 cm³/min and 10-20 cm³/min. The atmosphere within the sputtering chamber 103 is controlled such that the inert gas is separated into positively charged ions and negatively charged electrons, thereby creating a plasma. AC power, in a range between 3-5 kW, is applied to the magnetron 102 to negatively charge the target 120. The positively charged ions introduced are accelerated into the negatively biased target 120. The positively charged ions are accelerated and strike the negatively charged target 120 with enough force to dislodge and eject microscopic molecules of material from the target 120. Such molecules of material then condense onto the wafer surface. The magnetic field generated by the magnet assemblies 112A and 112B of the internal assembly 111 aids in this process by confining negatively charged electrons at the surface of the target 120. The confined negatively charged electrons attract the positively charged ions to the surface of the target 120, which then dislodge molecules of target material. In some embodiments, the magnetic field is tuned such that the negatively charged electrons are optimally arranged on the target 120 for uniform deposition and faster deposition rates of molecules from the target 120 onto the wafer 10.

Once the wafer 10 has been processed, the wafer 10 is allowed to cool and then the wafer 10 is removed from the sputtering chamber 103. The vertical rod 182 lifts and returns the wafer chuck 140 to the “wafer loading” position, where the plurality of pin assemblies 150 release the wafer 10 and remain open and in position to receive another wafer 10. The wafer 10 can be removed from the sputtering chamber 103 through the slot 176.

In some embodiments, the system 100 is in communication with a computing system for control of the magnetron 102 and the wafer handling apparatus 104. The computing system can, in some embodiments, receive feedback from the magnetron 102 and the wafer handling apparatus 104 to adjust parameters for real-time control of the wafer 140 including but not limited to: wafer temperature, wafer position, parameters indicative of magnetron function, and data related to film thickness, uniformity, and/or integrity. The computing system is also operable to store and execute instructions for control of the magnetron 102 and the wafer handling apparatus 104, and in particular, to control the rotational assembly 170 and lifting assembly 172 of the wafer handling apparatus 104 and to control the target 120 and magnet assemblies 112A and 112B of the magnetron 102. In some embodiments, the computing system is also operable to control the thermoelectric assembly 145 and to control a flow of gas from both the gas assembly 146 of the wafer handling apparatus 104 and the gas distribution system 132 of the magnetron 102.

### Results and Test Data

The system 100 employs the wafer handling apparatus 104 with the wafer chuck 140 to achieve high quality in ultrathin AlN films, offering rotation of the wafer 10 with in-situ heating at high temperatures. High temperatures provide high activation energy to AlN ad-atoms, resulting in better surface diffusion and thereby good crystals in ultrathin AlN Films. The wafer-to-target distance can also be adjusted by lowering the wafer 10 into the sputtering chamber 103 to a selected height relative to the target 120. The sputtering chamber 103 is able to achieve a full width at half maximum (FWHM) of the rocking curve of about 2.0 degree in 30 nm films, which is unprecedented compared to previously reported results. The FWHM value achieved by the system 100 is highly competitive with other conventional systems, especially when considering the ultra-thin 30 nm thickness of the film.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

What is claimed is:

1. A method for depositing an ultra-thin film onto a wafer, comprising:
providing a sputtering chamber, the sputtering chamber being collectively defined by a wafer handling apparatus and a magnetron;
placing the wafer onto a wafer chuck of the wafer handling apparatus;
moving the wafer chuck with the wafer to a first distance to the magnetron;
introducing a gas into the sputtering chamber such that the gas is separated into a plasma, wherein the plasma includes gas ions;
applying a first negative potential to at least one sputtering target of the magnetron while the wafer chuck with the wafer is at the first distance to the magnetron;
rotating the wafer at a first rotational speed using the wafer chuck of the wafer handling apparatus during the application of the first negative potential to at least one sputtering target of the magnetron; and
removing the wafer from the wafer chuck after the application of the first negative potential to at least one sputtering target of the magnetron.

2. The method of claim 1, further comprising continuously rotating the wafer at the first rotational speed using the wafer chuck of the wafer handling apparatus during the application of the first negative potential to at least one sputtering target of the magnetron.

3. The method of claim 1, further comprising variably rotating the wafer at different rotational speeds using the wafer chuck of the wafer handling apparatus during the application of the first negative potential to at least one sputtering target of the magnetron.

4. The method of claim 1, further comprising applying an in-situ etching process to the wafer prior to applying the first negative potential to the sputtering target of the magnetron.

5. The method of claim 1, further comprising securing the wafer against an underside of the wafer chuck of the wafer handling apparatus using a plurality of pin assemblies.

6. The method of claim 1, further comprising:
moving the wafer chuck with the wafer to a second distance to the magnetron;
applying a second negative potential to at least one sputtering target of the magnetron while the wafer chuck with the wafer is at the second distance to the magnetron; and
removing the wafer from the wafer chuck after the application of the second negative potential to at least one sputtering target of the magnetron.

7. The method of claim 6, further comprising rotating the wafer at a second rotational speed using the wafer chuck of the wafer handling apparatus during the application of the second negative potential to at least one sputtering target of the magnetron.

8. The method of claim 7, further comprising continuously rotating the wafer at the second rotational speed using the wafer chuck of the wafer handling apparatus during the application of the second negative potential to at least one sputtering target of the magnetron.

9. The method of claim 7, further comprising variably rotating the wafer at different rotational speeds using the wafer chuck of the wafer handling apparatus during the application of the second negative potential to at least one sputtering target of the magnetron.

10. A method for depositing an ultra-thin film onto a wafer, comprising:
providing a sputtering chamber, the sputtering chamber being collectively defined by a wafer handling apparatus and a magnetron;
placing the wafer onto a wafer chuck of the wafer handling apparatus;
moving the wafer chuck with the wafer to a first distance to the magnetron;
introducing a gas into the sputtering chamber such that the gas is separated into a plasma, wherein the plasma includes gas ions; and
applying a first negative potential to at least one sputtering target of the magnetron while the wafer chuck with the wafer is at the first distance to the magnetron;
moving the wafer chuck with the wafer to a second distance to the magnetron;
applying a second negative potential to at least one sputtering target of the magnetron while the wafer chuck with the wafer is at the second distance to the magnetron; and
removing the wafer from the wafer chuck after the application of the second negative potential to at least one sputtering target of the magnetron.

11. The method of claim 10, further comprising securing the wafer against an underside of the wafer chuck of the wafer handling apparatus using a plurality of pin assemblies.

12. The method of claim 10, further comprising applying an in-situ etching process to the wafer prior to applying the first negative potential to the sputtering target of the magnetron.

13. The method of claim 10, further comprising rotating the wafer at a first rotational speed using the wafer chuck of the wafer handling apparatus during the application of the first negative potential to at least one sputtering target of the magnetron.

14. The method of claim 13, further comprising continuously rotating the wafer at the first rotational speed using the wafer chuck of the wafer handling apparatus during the application of the first negative potential to at least one sputtering target of the magnetron.

15. The method of claim 13, further comprising variably rotating the wafer at different rotational speeds using the wafer chuck of the wafer handling apparatus during the application of the first negative potential to at least one sputtering target of the magnetron.

16. The method of claim 13, further comprising rotating the wafer at a second rotational speed using the wafer chuck of the wafer handling apparatus during the application of the second negative potential to at least one sputtering target of the magnetron.

17. The method of claim 16, further comprising continuously rotating the wafer at the second rotational speed using the wafer chuck of the wafer handling apparatus during the application of the second negative potential to at least one sputtering target of the magnetron.

18. The method of claim 16, further comprising variably rotating the wafer at different rotational speeds using the wafer chuck of the wafer handling apparatus during the application of the second negative potential to at least one sputtering target of the magnetron.

19. A system for depositing an ultra-thin film onto a wafer, comprising:
a sputtering chamber;
a magnet assembly positioned proximate to a sputtering target and configured for manipulating a magnetic field at a surface of the sputtering target;
a wafer handling apparatus positioned above the sputtering target having a vertical rod and a wafer chuck, the wafer chuck having a thermoelectric assembly configured to apply heat to the wafer;
a lifting assembly for lifting or lowering the wafer chuck;
a rotational assembly in communication with the vertical rod for rotating the wafer chuck; and
a plurality of pin assemblies to receive the wafer and hold the wafer against an underside of the wafer chuck.

20. The system of claim 19, wherein the plurality of pin assemblies are defined annularly around the wafer chuck for receipt of a wafer.
